(19) United States
(12) Patent Application Publication
(10) Pub. No.: US 2024/0339531 A1
(43) Pub. Date: Oct. 10, 2024

(54) CHANNEL WIDTH MODULATION

(71) Applicant: Taiwan Semiconductor Manufacturing Company, Ltd., Hsinchu (TW)

(72) Inventors: Guan-Lin Chen, Hsinchu City (TW); Kuo-Cheng Chiang, Hsinchu County (TW); Shi Ning Ju, Hsinchu City (TW); Jung-Chien Cheng, Tainan City (TW); Chih-Hao Wang, Hsinchu (TW)

(21) Appl. No.: 18/365,470

(22) Filed: Aug. 4, 2023

Related U.S. Application Data
(60) Provisional application No. 63/494,852, filed on Apr. 7, 2023.

(51) Int. Cl. H01L 29/775; H01L 29/06; H01L 29/08; H01L 29/423; H01L 29/66; H01L 29/786

(52) U.S. Cl. CPC H01L 29/775; H01L 29/0673; H01L 29/0847; H01L 29/42392; H01L 29/66439; H01L 29/66545; H01L 29/66553; H01L 29/78696

(57) ABSTRACT

A semiconductor device according to the present disclosure includes a first base fin and a second base fin extending from a substrate, an isolation feature disposed between the first base fin and the second base fin, a first dummy epitaxial layer disposed on the first base fin, a second dummy epitaxial layer disposed on the second base fin, a first insulator layer over the first dummy epitaxial layer, a second insulator layer over the second dummy epitaxial layer, a first source/drain feature disposed on the first insulator layer, a second source/drain feature disposed on the second insulator layer. A thickness of the first dummy epitaxial layer measured from a top surface of the first base fin is smaller than a thickness of the second dummy epitaxial layer measured from a top surface of the second base fin.

### PRIORITY DATA

The present application claims the benefit of U.S. Provisional Application No. 63/494,852, filed Apr. 7, 2023, the entirety of which is herein incorporated by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT). Because the channel region of an GAA transistor may include nanowires or nanosheets and its configuration resembles a bridge, a GAA transistor may also be referred to a multi-bridge-channel (MBC) transistor, a nanowire transistor, or a nanosheet transistor. The nanosheets and nanowires may be generally referred to as nanostructures.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2-29 illustrate fragmentary cross-sectional and perspective views of a workpiece during various fabrication stages in the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. As used herein, source/drain region(s) may refer to a source or a drain, individually or collectively, dependent upon the context.

An IC device may include high performance transistors an low power transistors. In generally, transistors with a greater effective channel width (Weff) tend to have higher performance in terms of switching speed and the on-state current. Transistors with a smaller effective channel width (Weff) tend to have lower power consumption. For example, a logic hybrid cell may include both high performance transistors and low power transistors. In some existing technologies, GAA transistors having active regions of different width are provided as a solution to provide a variety of effective channel widths. Fabrication of transistors with different active region widths is not without it challenges. This is especially true when the active region has a small width, which makes it challenging to form inner spacer features and source/drain features.

The present disclosure provides processes and structures to provide GAA transistors with different effective channel widths. The present disclosure provides at least two approaches to adjust an effective channel width (Weff) while maintaining a uniform device footprint. A first approach is to displace at least one top channel members by a helmet layer. A second approach is to control a height of a dummy epitaxial layer and an insulator have below a source/drain feature. The first approach physically removes available channel members and the second approach disabled available channel members. By varying the number of available channel members in an GAA transistor, the present disclosure offers both high performance and low power transistors.

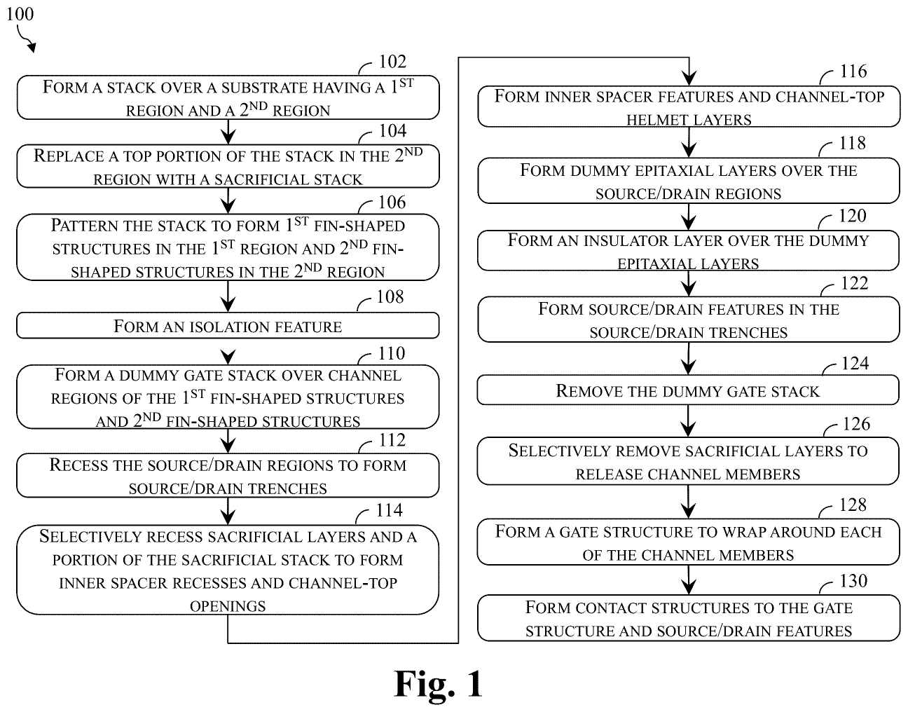

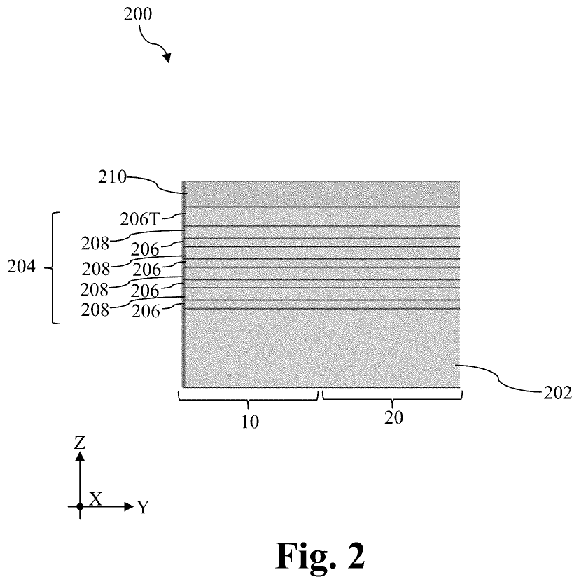

The various aspects of the present disclosure will now be described in more detail with reference to the figures. FIG. 1 illustrates a flowchart of a method 100 of forming a semiconductor device. Method 100 is merely an example and is not intended to limit the present disclosure to what is explicitly illustrated in method 100. Additional steps may be provided before, during and after method 100, and some steps described can be replaced, eliminated, or moved around for additional embodiments of the methods. Not all steps are described herein in detail for reasons of simplicity. Method 100 is described below in conjunction with FIGS. 2-29, which illustrate fragmentary perspective or cross-sectional views of a workpiece 200 at different stages of fabrication according to embodiments of method 100. Because a semiconductor device will be formed from the workpiece 200, the workpiece 200 may be referred to as a semiconductor device 200 as the context requires. Throughout FIGS. 2-29, the Y direction, the X direction, and the Z direction are perpendicular to one another and are used consistently. For example, the Y direction in one figure is parallel to the Y direction in a different figure. Additionally, throughout the present disclosure, like reference numerals are used to denote like features.

Referring to FIGS. 1 and 2, method 100 includes a block 102 where a stack 204 is formed over a substrate 202 that has a first region 10 and a second region 20. In one embodiment, the substrate 202 may be a silicon (Si) substrate. In some other embodiments, the substrate 202 may include other semiconductor materials such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure or a germanium-on-insulator (GeOI) structure. In some embodiments, the substrate 202 may include one or more well regions, such as n-type well regions doped with an n-type dopant (i.e., phosphorus (P) or arsenic (As)) or p-type well regions doped with a p-type dopant (i.e., boron (B)), for forming different types of devices. The doping the n-type wells and the p-type wells may be formed using ion implantation or thermal diffusion.

Referring still to FIG. 2, the stack 204 may include a plurality of channel layers 208 interleaved by a plurality of sacrificial layers 206. The channel layers 208 and the sacrificial layers 206 may have different semiconductor compositions. In some implementations, the channel layers 208 are formed of silicon (Si) and sacrificial layers 206 are formed of silicon germanium (SiGe). In these implementations, the additional germanium content in the sacrificial layers 206 allow selective removal or recess of the sacrificial layers 206 without substantial damages to the channel layers 208. In some embodiments, the sacrificial layers 206 and channel layers 208 may be deposited using an epitaxial process. The stack 204 may be epitaxially deposited over the substrate 202 using CVD deposition techniques (e.g., vapor-phase epitaxy (VPE) and/or ultra-high vacuum CVD (UHV-CVD)), molecular beam epitaxy (MBE), and/or other suitable processes. The sacrificial layers 206 and the channel layers 208 are deposited alternatingly, one-after-another, to form the stack 204. Besides the plurality of channel layers 208 and the plurality of sacrificial layers 206, the stack 204 may also include a top sacrificial layer 206T, which is thicker than any one of the plurality of the sacrificial layers 206. The greater thickness of the top sacrificial layer 206T protects the underlying stacks and provides cushion for a subsequent planarization process. It is noted that four (4) layers of the sacrificial layers 206 and four (4) layers of the channel layers 208 are alternately and vertically arranged as illustrated in FIG. 2, which is for illustrative purposes only and not intended to be limiting beyond what is specifically recited in the claims. The number of layers depends on the desired number of channels members for the semiconductor device 200. In some embodiments, the number of the channel layers 208 is between 2 and 10.

To prepare for the subsequent patterning process, a hard mask layer 210 is deposited over the stack 204. The hard mask layer 210 serves as an etch mask to pattern the stack 204 and a portion of the substrate 202. In some embodiments, the hard mask layer 210 may be deposited using CVD, plasma-enhanced CVD (PECVD, atomic layer deposition (ALD), plasma-enhanced ALD (PEALD), or a suitable deposition method. The hard mask layer 210 may be a single layer or a multilayer. When the hard mask layer 210 is a multi-layer, it may include a first layer and a second layer disposed over the first layer. In one embodiment, the first layer may be a pad oxide and the second layer may be a pad nitride layer. For ease of reference, the substrate 202 and structures formed thereon at each step of method 100 may be collectively referred to as a workpiece 200. The workpiece 200 shown in FIG. 2 includes the substrate 202, the stack 204 over the substrate 202, and a hard mask layer 210 over the stack 204. The substrate 202 of the workpiece 200 includes a first region 10 and a second region 20.

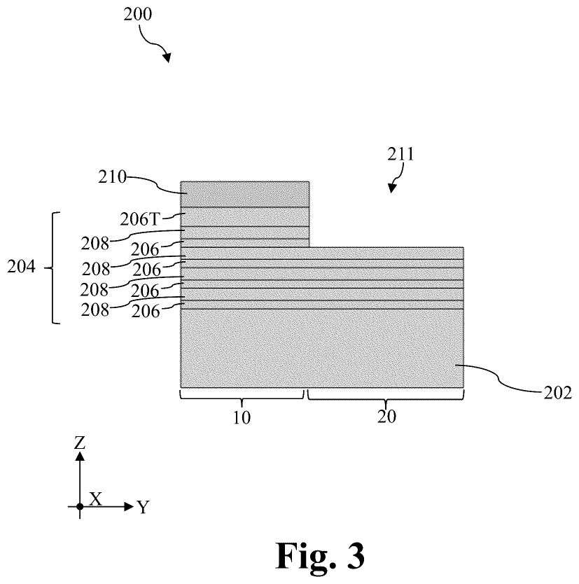

Referring to FIGS. 1 and 3-5, method 100 includes a block 104 where a top portion of the stack 204 in the second region 20 is replaced with a sacrificial stack 2060. In order to reduce the effective channel width in the second region 20, a topmost sacrificial layer 206, a topmost channel layer 208, the top sacrificial layer 206T of the stack 204 in the second region 20 is selectively removed to form a recess 211 shown in FIG. 3. While not explicitly shown in the figures, the selective removal of the top portion of the stack in the second region 20 at block 104 includes a combination of photolithography and etch steps. A photoresist layer is deposited over the hard mask layer 210 using spin-on coating. The deposited photoresist layer may undergo an pre-exposure baking process, exposure to radiation reflected from or transmitted through a photomask, a post-exposure baking process, and developing process, so as to form a patterned photoresist. The hard mask layer 210 is then etched using the patterned photoresist as an etch mask to form a patterned hard mask layer 210. The patterned hard mask layer 210 is then applied as an etch mask to etch the stack 204 in the second region 20 to form the recess 211. Appropriate etch process at block 104 may be a dry etch process. In some embodiments, the etch process at block 104 may be a dry etch process (e.g., a reactive ion etching (RIE) process) that includes use of an oxygen-containing gas (e.g., (2), a fluorine-containing gas (e.g., SF₆ or NF₃), or a chlorine-containing gas (e.g., Cl₂ and/or BCl₃). A cleaning may be performed to remove debris and contaminants after the etching process.

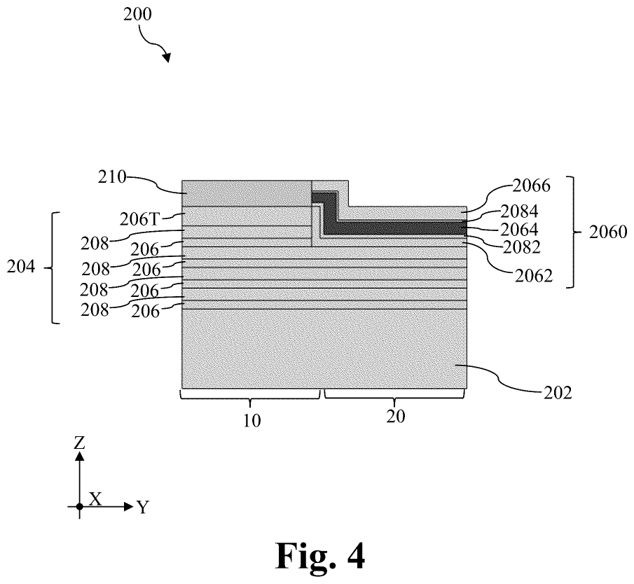

Referring to FIG. 4, a sacrificial stack 2060 is then epitaxially deposited over the recess 211 using CVD deposition techniques (e.g., vapor-phase epitaxy (VPE) and/or ultra-high vacuum CVD (UHV-CVD)), molecular beam epitaxy (MBE), and/or other suitable processes. In some embodiments represented in FIG. 4, the sacrificial stack 2060 includes a first sacrificial layer 2062, a high-germanium layer 2064 over the first sacrificial layer 2062, and a second sacrificial layer 2066 over the high-germanium layer 2064. To facilitate the selective etching of the high-germanium layer 2064, the high-germanium layer 2064 is sandwiched between a first silicon control layer 2082 and a second silicon control layer 2084. The first silicon control layer 2082 is sandwiched between the first sacrificial layer 2062 and the high-germanium layer 2064. The second silicon control layer 2084 is sandwiched between the second sacrificial layer 2066 and the high-germanium layer 2064. Because semiconductor materials, such as silicon, germanium, or silicon germanium is unlike to be epitaxially deposited on dielectric surfaces, the patterned hard mask layer 210 over the first region 10 serves as a deposition mask during the deposition of the sacrificial stack 2060. To ensure that the high-germanium layer 2064 will be selectively removed with respect to other sacrificial layers, it has a greater germanium content. In some embodiments, the high-germanium layer 2064 includes a germanium content between about 30% and about 50% while the sacrificial layers 206, the first sacrificial layer 2062, and the second sacrificial layer 2066 includes a germanium content between about 20% and about 30%. Each of the first silicon control layer 2082 and the second silicon control layer 2084 may consist essentially of silicon (Si). According to the present disclosure, the first silicon control layer 2082 and the second silicon control layer 2084 are to be completely removed after the high-germanium layer 2064 is removed. To ensure satisfactory removal of the first silicon control layer 2082 and the second silicon control layer 2084, each of them may be substantially thinner than the high-germanium layer 2064. In some embodiments, the high-germanium layer 2064 may have a thickness (along the Z direction) between about 10 nm and about 30 nm while each of the first silicon control layer 2082 and the second silicon control layer 2084 may have a thickness between about 1 nm and about 5 nm. As illustrated in FIG. 4, because the epitaxial deposition initiates on all available semiconductor surfaces, each layer in the sacrificial stack 2060 may conform to the surfaces of the recess 211. That is, each of the layers in the sacrificial stack 2060 includes at least one horizontal portion and one vertical portion.

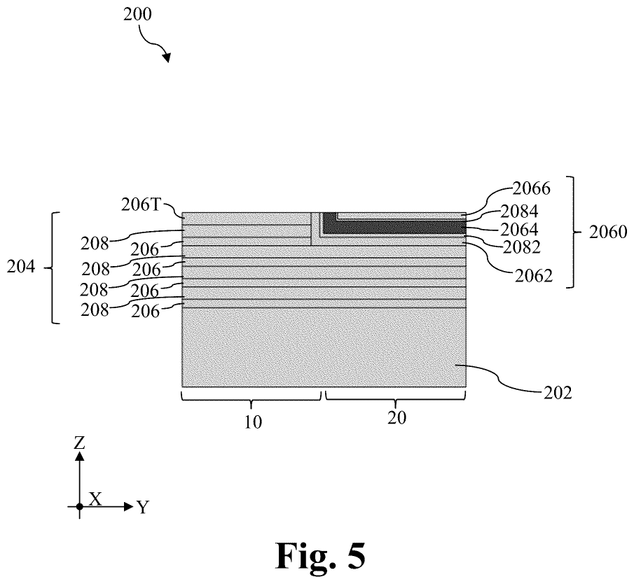

Referring to FIG. 5, after the deposition of the sacrificial stack 2060, the workpiece 200 is planarized to remove the patterned hard mask layer 210 over the first region 10. The planarization may be carried out by chemical mechanical polishing (CMP). As illustrated in FIG. 5, the planarization may continue until a top portion of the top sacrificial layer 206T is removed. As described above, the top sacrificial layer 206T serves as a cushion during the planarization operation shown in FIG. 5 and for that reason, is thicker than the sacrificial layers 206.

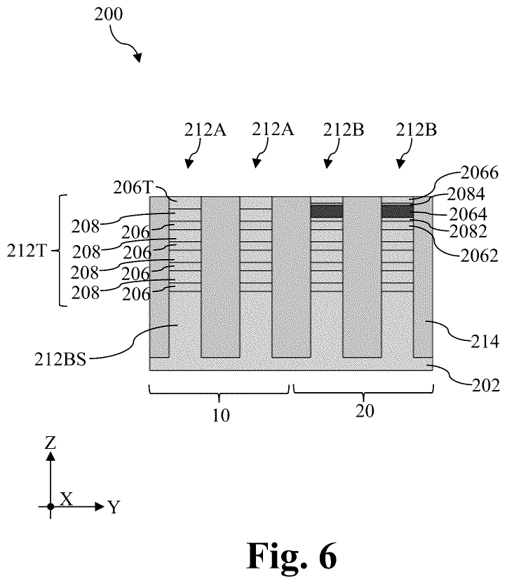

Referring to FIGS. 1 and 6, method 100 includes a block 106 where the stack 204 is patterned to form a first fin-shaped structure 212A in the first region 10 and a second fin-shaped structure 212B in the second region 20. At block 106, the stack 204 and a portion of the substrate 202 in the first region 10 are patterned to form the first fin-shaped structure 212A. The sacrificial stack 2060, the stack 204, and a portion of the substrate 202 in the second region 20 are patterned to form the second fin-shaped structure 212B. As shown in FIG. 6, each of the first fin-shaped structure 212A and the second fin-shaped structure 212B includes a base portion 212BS formed from a portion of the substrate 202 and a top portion 212T formed from the stack 204 or the stack 204 and the top sacrificial layer 206T. The top portion 212T is disposed over the base portion 212BS. Each of the first fin-shaped structure 212A and the second fin-shaped structure 212B extends lengthwise along the X direction and extend vertically along the Z direction from the substrate 202. The first fin-shaped structure 212A and the second fin-shaped structure 212B may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern a hard mask layer and then the patterned hard mask layer may be used to etching the stack 204 (and the sacrificial stack 2060) and the substrate 202 to form the first fin-shaped structure 212A and the second fin-shaped structure 212B. The etching process can include dry etching, wet etching, reactive ion etching (RIE), and/or other suitable processes. In some embodiments represented in FIG. 6, two first fin-shaped structures 212A are formed in the first region 10 and two second fin-shaped structures 212B in the second region 20. A top surface of each of the second fin-shaped structures 212B includes the second silicon control layer 2084.

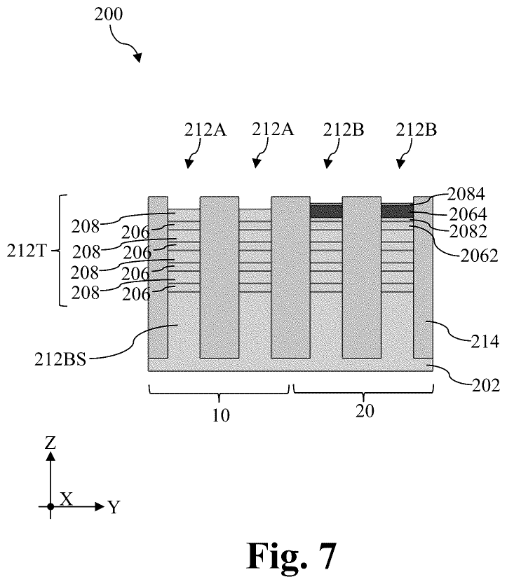

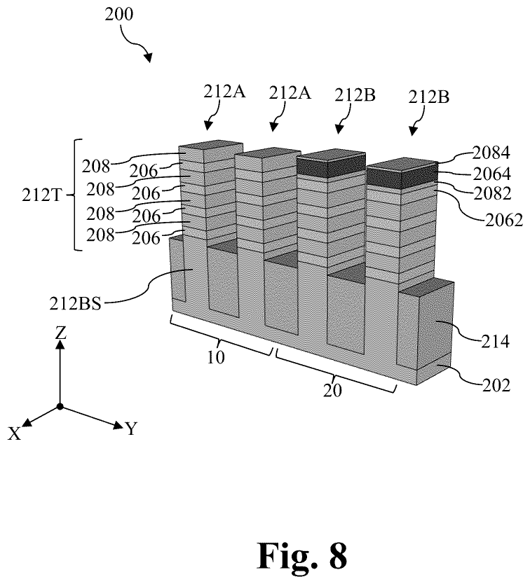

Referring to FIGS. 1 and 6-8, method 100 includes a block 108 where an isolation feature 214 is formed. After the first fin-shaped structure 212A and the second fin-shaped structure 212B are formed, the isolation feature 214 shown in FIG. 8 is formed between any two of the first fin-shaped structures 212A and the second fin-shaped structures 212B. The isolation feature 214 may also be referred to as a shallow trench isolation (STI) feature 214. In an example process, as shown in FIG. 6, a dielectric material for the isolation feature 214 is first deposited over the workpiece 200, filling the trenches between the first fin-shaped structures 212A and the second fin-shaped structures 212B with the dielectric material. In some embodiments, the dielectric material may include silicon oxide, silicon nitride, silicon oxynitride, fluorine-doped silicate glass (FSG), a low-k dielectric, combinations thereof, and/or other suitable materials. In various examples, the dielectric material may be deposited by a CVD process, a subatmospheric CVD (SACVD) process, a flowable CVD (FCVD) process, an ALD process, spin-on coating, and/or other suitable process. Referring to FIG. 7, with the help of the dielectric material, the remaining top sacrificial layer 206T over the first region 10 and the second sacrificial layer 2066 over the second region 20 are selectively removed. A dry etch process or a wet etch process that is selective to silicon germanium may be used to remove remaining the top sacrificial layer 206T and the second sacrificial layer 2066. An example wet etch process may include acetic acid (CH₃COOH), hydrogen peroxide (H₂O₂), and hydrofluoric acid (HF). After the removal of the top sacrificial layer 206T and the second sacrificial layer 2066, the deposited dielectric material is then thinned and planarized, for example by a chemical mechanical polishing (CMP) process. The planarized dielectric material is further recessed or etched back by a dry etching process, a wet etching process, and/or a combination thereof to form the isolation feature 214, as shown in FIG. 8. In some embodiments, the etching back continuous until top surfaces of the isolation feature 214 is below an interface between the base portion 212BS and the top portion 212T. As shown in FIG. 8, the top portions 212T of the first fin-shaped structures 212A and the second fin-shaped structures 212B rise above the isolation feature 214 while the base portions 212BS are surrounded by the isolation feature 214.

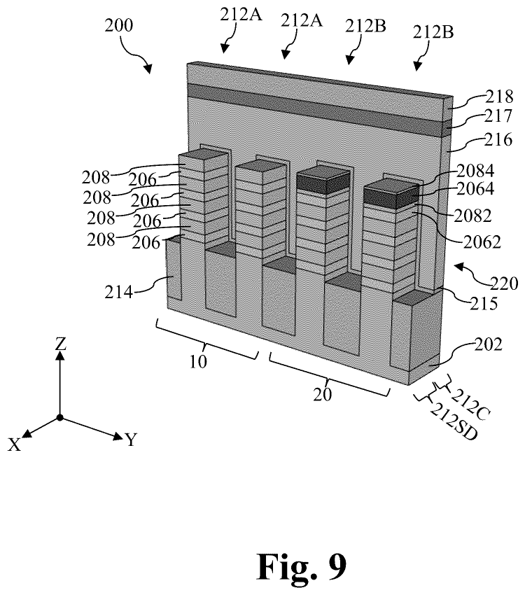

Referring to FIGS. 1 and 9, method 100 includes a block 110 where a dummy gate stack 220 is formed over channel regions 212C of the first fin-shaped structure 212A and the second fin-shaped structure 212B. In some embodiments, a gate replacement process (or gate-last process) is adopted where the dummy gate stack 220 serves as a placeholder for a functional gate structure. Other processes and configuration are possible. As shown in FIG. 9, the dummy gate stack 220 includes a dummy dielectric layer 215 and dummy electrode 216 disposed over the dummy dielectric layer 215. In order to pattern the dummy gate stack 220, a first gate-top hard mask 217 and a second gate-top hard mask 218 may be formed over the dummy electrode 216. The regions of the first fin-shaped structures 212A and the second fin-shaped structures 212B underlying the dummy gate stack 220 may be referred to as channel regions 212C. Each of the channel regions 212C is sandwiched between two source/drain regions 212SD (only one shown in FIG. 9 for simplicity) for source/drain formation. In an example process, the dummy dielectric layer 215 is blanketly deposited over the workpiece 200 by CVD. A material layer for the dummy electrode 216 is then blanketly deposited over the dummy dielectric layer 215. The dummy dielectric layer 215 and the material layer for the dummy electrode 216 are then patterned using photolithography processes to form the dummy gate stack 220. In some embodiments, the dummy dielectric layer 215 may include silicon oxide and the dummy electrode 216 may include polycrystalline silicon (polysilicon). The first gate-top hard mask 217 may include silicon oxide and the second gate-top hard mask 218 may include silicon nitride.

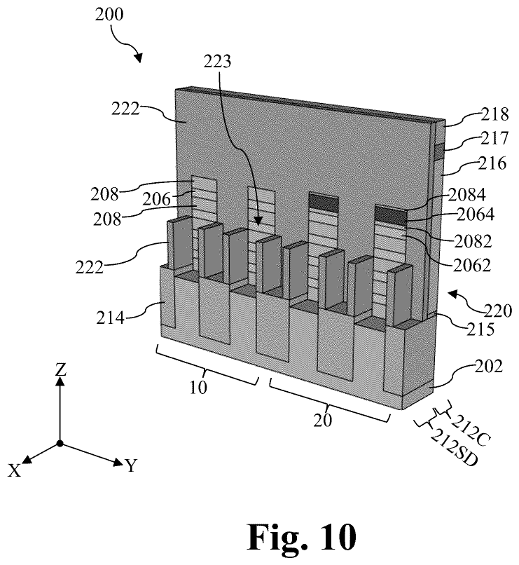

Referring to FIGS. 1 and 10, method 100 includes a block 112 where the source/drain regions 212SD are recessed to form source/drain trenches 223. Operations at block 112 include not only recessing of the source/drain regions 212SD but also deposition of at least one gate spacer 222 along sidewalls of the dummy gate stack 220. The at least one gate spacer 222 may include one or more gate spacer layers. Dielectric materials for the at least one gate spacer 222 may be selected to allow selective removal of the dummy gate stack 220 without substantially damaging the at least one gate spacer 222. Suitable dielectric materials may include silicon nitride, silicon oxycarbonitride, silicon carbonitride, silicon oxide, silicon oxycarbide, silicon carbide, silicon oxynitride, and/or combinations thereof. In an example process, the at least one gate spacer 222 may be conformally deposited over the workpiece 200 using CVD, subatmospheric CVD (SACVD), or ALD. After the deposition of the at least one gate spacer 222, the workpiece 200 is subject to an anisotropic dry etch to recess the source/drain regions 212SD of the first fin-shaped structures 212A and the second fin-shaped structures 212B. For example, the anisotropic dry etch process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 10, the source/drain trenches 223 are formed after the top portion 212T (shown in FIG. 8) and a portion of the base portion 212BS (shown in FIG. 8) of the first fin-shaped structures 212A and the second fin-shaped structures 212B in the source/drain regions 212SD are etched away. Each of the source/drain trenches 223 is defined between two portions of the at least one gate spacer 222 along the Y direction.

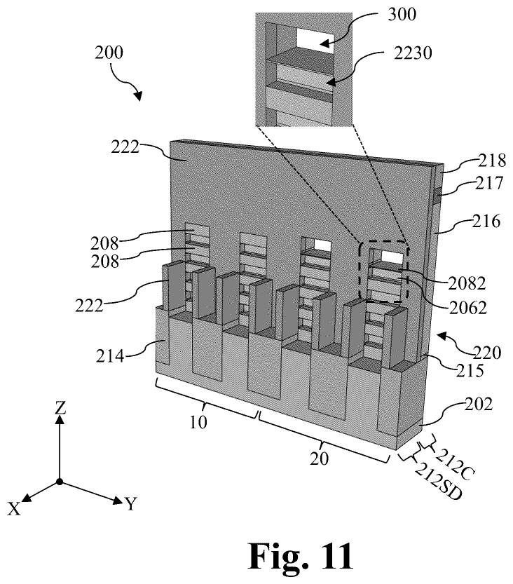

Referring to FIGS. 1 and 11, method 100 includes a block 114 where the sacrificial layers 206 and a portion of the sacrificial stack 2060 are selectively recessed to form inner spacer recesses 2230 and channel-top openings 300. After the operations at block 112, sidewalls of the plurality of channel layers 208, the plurality of sacrificial layers 206, the first sacrificial layer 2062, and the high-germanium layer 2064 in the channel regions 212C are exposed. At block 114, the sacrificial layers 206 and the first sacrificial layer 2062 exposed in the source/drain trench 223 are selectively and partially recessed to form inner spacer recesses 2230, while the exposed channel layers 208 are substantially unetched. The high-germanium layer 2064, due to its greater germanium content, etches faster and may be completely removed to form the channel-top openings 300. In an embodiment where the channel layers 208 consist essentially of silicon (Si) and sacrificial layers 206 and the first sacrificial layer 2062 consist essentially of silicon germanium (SiGe), the selective and partial recess of the sacrificial layers 206 and the first sacrificial layer 2062 may include a SiGe oxidation process followed by a SiGe oxide removal. In that embodiments, the SiGe oxidation process may include use of ozone (03). In some other embodiments, the selective recess may be a selective isotropic etching process (e.g., a selective dry etching process or a selective wet etching process), and the extent at which the sacrificial layers 206 and the first sacrificial layer 2062 are recessed is controlled by duration of the etching process. The selective dry etching process may include use of one or more fluorine-based etchants, such as fluorine gas or hydrofluorocarbons. The selective wet etching process may include use of hydrogen fluoride (HF) or ammonium hydroxide (NH₄OH). As described above, due to the greater germanium content, the etching process that recesses the sacrificial layers 206 and the first sacrificial layer 2062 may completely remove the high-germanium layer 2064 in the second region 20 to form the channel-top openings 300. As shown in the blown-up view in FIG. 11, at least a portion of the first silicon control layer 2082 and the second silicon control layer 2084 may remain.

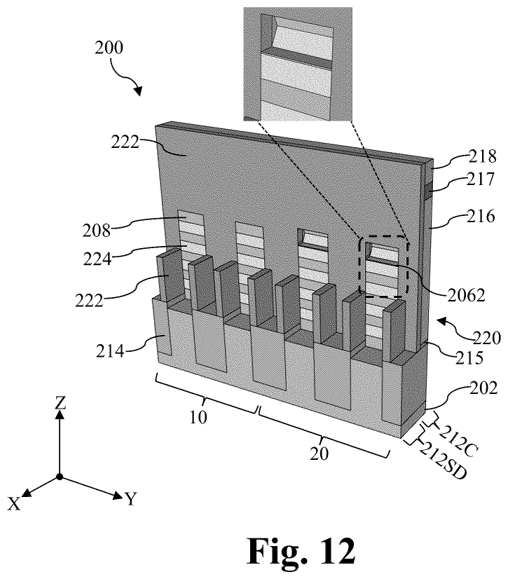

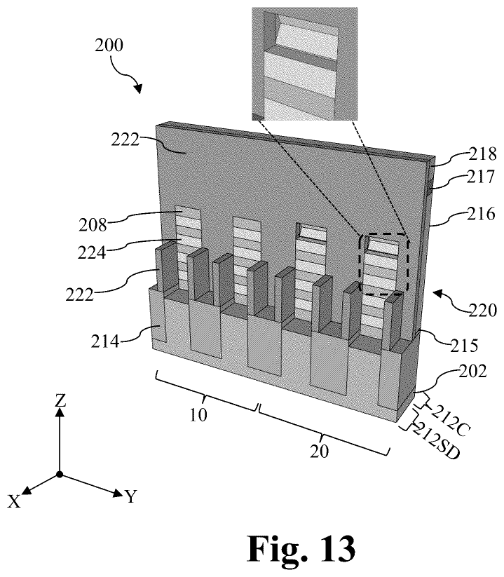

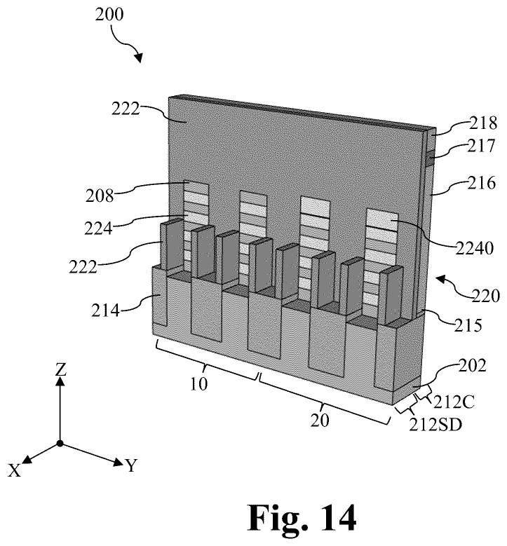

Referring to FIGS. 1 and 12-14, method 100 includes a block 116 where inner spacer features 224 and channel-top helmet layers 2240 are formed. Referring to FIG. 12, after the formation of the inner spacer recesses 2230 and the channel-top openings 300, a dielectric material is then conformally deposited using CVD or ALD over the workpiece 200, including over and into the inner spacer recesses 2230 and channel-top openings 300. The dielectric material deposited at block 116 may include silicon nitride, silicon carbonitride, silicon oxycarbide, silicon oxycarbonitride, or silicon oxynitride. Thereafter, the deposited dielectric material is etched back to form inner spacer features 224, as illustrated in FIG. 12. As shown in the blown-up view in FIG. 12, the channel-top openings 300 may be partially filled by the dielectric material. Referring to FIG. 13, the deposited dielectric material is etched back to form the inner spacer features 224. While the etching back may partially remove the leftover first silicon control layer 2082 and second silicon control layer 2084, block 116 may include separate operations to selectively remove the first silicon control layer 2082 and the second silicon control layer 2084. As illustrated in FIG. 13, the channel-top openings 300 and helmet features (to be described below) to be deposited in the channel-top openings 300 function to displace the topmost channel layers 208 that are found in the first region 10 but are not found in the second region 20. When the first silicon control layer 2082 and the second silicon control layer 2084 are not substantially removed, they may inadvertently become channels that have different properties (such as different threshold voltages) from the intended channel members. Referring to FIG. 14, after the selective removal of the first silicon control layer 2082 and the second silicon control layer 2084, a dielectric material is again deposited over the workpiece 200, including the unfilled channel-top openings 300. The deposited dielectric material is then etched back to form the channel-top helmet layers 2240. A composition of the channel-top helmet layers 2240 may be similar to that of the inner spacer features 224. In some embodiments represented in FIG. 14, a thickness of the channel-top helmet layer 2240 along the Z direction may be between about 5 nm and about 15 nm.

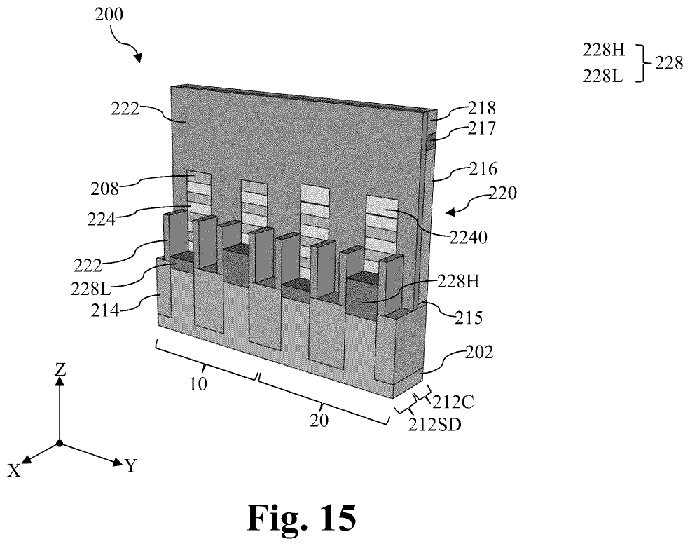

Referring to FIGS. 1 and 15, method 100 includes a block 118 where dummy epitaxial layers 228 are formed over source/drain regions 212SD. The dummy epitaxial layers 228 of the present disclosure serve at least two functions. First, they reduce leakage into the substrate 202. Second, they may be formed to different heights to deactivate channel members close to the base portion (212BS). The dummy epitaxial layers 228 may include undoped semiconductor material. In the depicted embodiments, the dummy epitaxial layers 228 includes undoped silicon (Si), undoped silicon germanium (SiGe), or undoped germanium (Ge). In these embodiments, the dummy epitaxial layers 228 may be deposited using vapor-phase epitaxy (VPE), ultra-high vacuum chemical vapor deposition (UHV-CVD), molecular beam epitaxy (MBE), and/or other suitable epitaxy deposition processes. As shown in FIG. 15, a portion of the dummy epitaxial layers 228 is sandwiched, along the Y direction, between two gate spacer portions 222. The dummy epitaxial layers 228 may be formed to have different heights to selectively deactivate a channel member close to the base portion (212BS). In some embodiments illustrated in FIG. 15, a low dummy epitaxial layer 228L and a tall dummy epitaxial layer 228H are formed. The low dummy epitaxial layers 228L stay clear of sidewall of the bottommost channel layers 208 and do not deactivate any channel member. The tall dummy epitaxial layers 228H completely cover sidewalls of the bottommost channel layers 208 and thereby deactivate them. The low dummy epitaxial layer 228 and tall dummy epitaxial layer 226 may be formed by depositing a dummy epitaxial layer in all regions and patterning the dummy epitaxial layer using photolithography techniques.

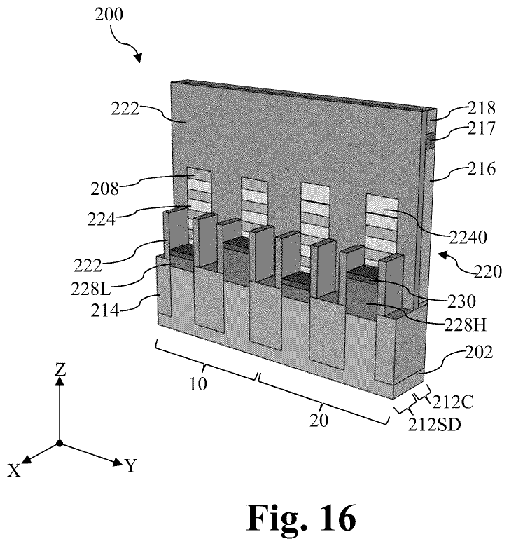

Referring to FIGS. 1 and 16, method 100 includes a block 120 wherein an insulator layer 230 is formed over the dummy epitaxial layers 228. In some embodiments, the insulator layer 230 includes silicon nitride, silicon oxynitride, silicon oxycarbonitride, silicon oxycarbide, silicon carbonitride, silicon oxide, aluminum oxide, or hafnium oxide and may be deposited using atomic layer deposition (ALD) or plasma-enhanced ALD (PE-ALD). As shown in FIG. 16, the insulator layer 230 is deposited over the dummy epitaxial layer 228. The insulator layer 230 also functions to reduce leakage into the bulk substrate 202. In some embodiments, represented in FIG. 16, the insulator layer 230 may be in direct contact with the inner spacer features 224. Because the insulator layer 230 does not need to withstand the etching during the release of the channel layers 208, it may be thinner than the inner spacer features 224. In some implementations, each of the inner spacer features may have a thickness between 7 nm and about 15 nm (measured along the X direction) while the insulator layer 230 may have a thickness between about 3 nm and about 8 nm along the Z direction. In an example process, a dielectric layer for the insulator layer 230 is conformally deposited on all exposed surfaces of the dummy epitaxial layer 228. Then a directional treatment is performed to selectively treat the dielectric layer on top-facing surfaces while the dielectric layer disposed along sidewalls of the dummy epitaxial layer 228 is untreated or less treated. A selective etch process is then performed to selectively remove the untreated portion of the dielectric layer to form the insulator layer 230.

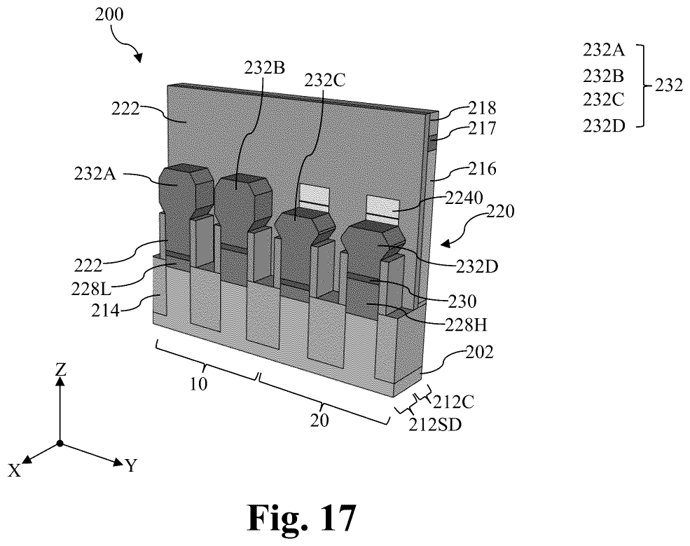

Referring to FIGS. 1 and 17, method 100 includes a block 122 wherein source/drain features 232 are formed in the source/drain trenches. Four source/drain features 232 are representatively illustrated in FIG. 17. A first source/drain feature 232A in the first region 10 is disposed over a low dummy epitaxial layer 228L. A second source/drain feature 232B in the first region 10 is disposed over a tall dummy epitaxial layer 228H. A third source/drain feature 232C in the second region 20 is disposed over a low dummy epitaxial layer 228L. A fourth source/drain feature 232D in the second region 20 is disposed over a tall dummy epitaxial layer 228H. The first source/drain feature 232A, the second source/drain feature 232B, the third source/drain feature 232C, and the fourth source/drain feature 232D may be collectively referred to as the source/drain features 232. The source/drain features 232 are selectively and epitaxially deposited on the exposed semiconductor surfaces of the channel layers 208 using an epitaxial process, such as vapor-phase epitaxy (VPE), ultra-high vacuum CVD (UHV-CVD), molecular beam epitaxy (MBE), and/or other suitable processes. Due to the epitaxial nature of the deposition, the source/drain features 232 are less likely to deposit on surfaces of the channel-top helmet layers 2240. As a result, top surfaces of the third source/drain feature 232C and the second source/drain feature 232D in the second region 20 are lower than top surfaces of the first source/drain feature 232A and the second source/drain feature 232B in the first region 10. The source/drain features 232 may be either n-type or p-type. When the source/drain features 232 are n-type, it may include silicon (Si) and may be doped with an n-type dopant, such as phosphorus (P) or arsenic (As). When the source/drain features 232 are p-type, it may include silicon germanium (SiGe) or germanium (Ge) and may be doped with a p-type dopant, such as boron (B) or gallium (Ga). Doping of the source/drain features 232 may be performed either in situ with their deposition or ex situ using an implantation process, such as a junction implant process. While not explicitly shown in the figures, the source/drain features 232 may include more than one epitaxial layers with different germanium contents or dopant concentrations.

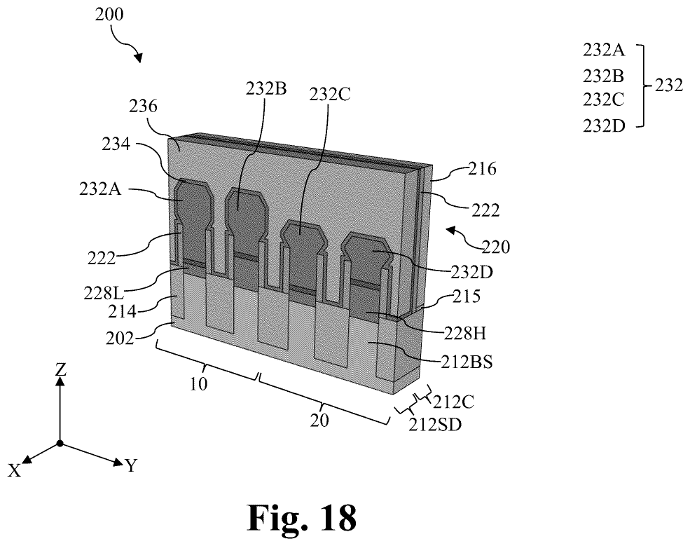

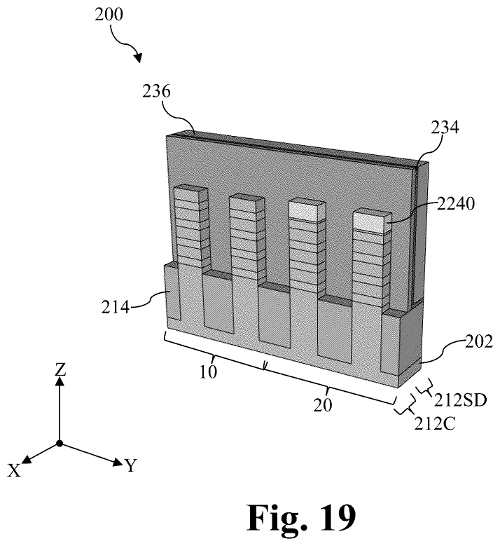

Referring to FIGS. 1 and 18-19, method 100 includes a block 124 where the dummy gate stack 220 is removed. Operations at block 124 may include deposition of a contact etch stop layer (CESL) 234 (shown in FIG. 18), deposition of an interlayer dielectric (ILD) layer 236 over the CESL 234 (shown in FIG. 18), an anneal process, planarization of the workpiece 200 (shown in FIG. 18), and selective removal of the dummy gate stack 220 from the channel region 212C (shown in FIG. 19). In an example process, the CESL 234 is first conformally deposited over the workpiece 200 and then the ILD layer 236 is blanketly deposited over the CESL 234. The CESL 234 may include silicon nitride or silicon oxynitride. The CESL 234 may be deposited using ALD, plasma-enhanced chemical vapor deposition (PECVD) process and/or other suitable deposition or oxidation processes. In some embodiments, the ILD layer 236 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In one embodiment, the ILD layer 236 includes silicon oxide. The ILD layer 236 may be deposited by spin-on coating, an FCVD process, or other suitable deposition technique. In some embodiments, after formation of the ILD layer 236, the workpiece 200 may be annealed to improve integrity of the ILD layer 236. To remove excess materials and to expose top surfaces of the dummy electrode 216 of the dummy gate stacks 220, a planarization process, such as a chemical mechanical polishing (CMP) process, may be performed to the workpiece 200 to provide a planar top surface. Top surfaces of the dummy electrode 216 are exposed on the planar top surface, as shown in FIG. 18.

Reference is then made to FIG. 19. After the dummy electrode 216 is exposed by planarization, the dummy gate stack 220 is removed from the workpiece 200 by a selective etch process. The selective etch process may be a selective wet etch process, a selective dry etch process, or a combination thereof. In the depicted embodiments, the selective etch process selectively removes the dummy dielectric layer 215 and the dummy electrode 216 without substantially damaging the channel-top helmet layer 2240. The removal of the dummy gate stack 220 results in a gate trench over the channel region 212C.

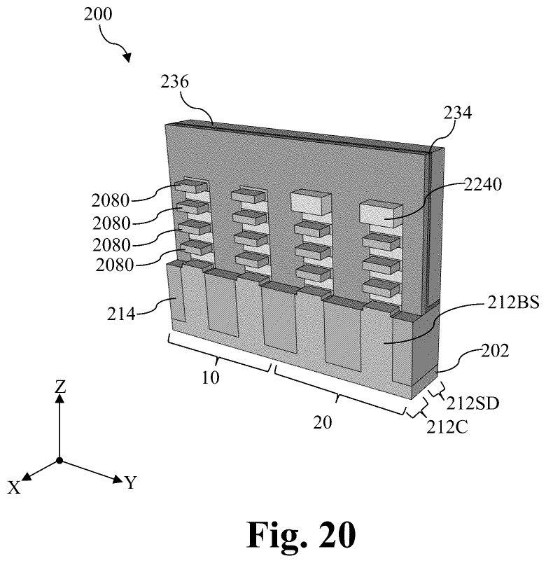

Referring to FIGS. 1 and 20, method 100 includes a block 126 where sacrificial layers 206 are selectively removed to release the channel layers 208 as channel members 2080. After the removal of the dummy gate stack 220, channel layers 208, sacrificial layers 206, and the channel-top helmet layer 2240 in the channel region 212C are exposed in the gate trenches. Due to their germanium content, the exposed sacrificial layers 206 between the channel layers 208 may be selectively removed to release the channel layers 208 to form channel members 2080, shown in FIG. 20. The channel members 2080 are vertically stacked along the Z direction. The selective removal of the sacrificial layers 206 may be implemented by selective dry etch, selective wet etch, or other selective etch processes. In some embodiments, the selective wet etching includes an APM etch (e.g., ammonia hydroxide-hydrogen peroxide-water mixture). In some alternative embodiments, the selective removal includes silicon germanium oxidation followed by a silicon germanium oxide removal. For example, the oxidation may be provided by ozone clean and then silicon germanium oxide removed by an etchant such as NH₄OH. With the removal of the sacrificial layers 206 in the channel region 212C, the inner spacer features 224, the channel-top helmet layers 2240, the channel members 2080, the top surface of the base portion 212BS, and the isolation feature 214 are exposed in the gate trench. FIG. 20 demonstrates how the formation of the channel-top helmet layers 2240 reduces the number of channel members 2080 in the second region 20. In the depicted embodiments, channel regions 212C in the first region 10 include four (4) vertically-stacked channel members 2080 while channel regions 212C in the second region 20 include only three (3) vertically-stacked channel members 2080. It should be understood that the number of channel members 2080 in each active region shown in FIG. 20 is for illustration purpose only. More or less channel members 2080 may be implemented in the first region 10 or the second region 20.

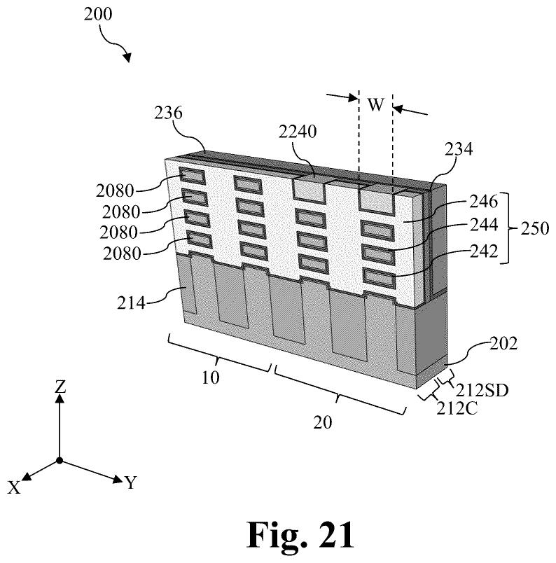

Referring to FIGS. 1 and 21, method 100 includes a block 128 where a gate structure 250 is formed to wrap around each of the channel members 2080. The gate structure 250 may include an interfacial layer 242 on the channel members 2080 and the base portions 212BS, a gate dielectric layer 244 on the interfacial layer 242, and a gate electrode layer 246 over the gate dielectric layer 244. In some embodiments, the interfacial layer 242 may include silicon oxide and may be formed as result of a pre-clean process. An example pre-clean process may include use of RCA SC-1 (ammonia, hydrogen peroxide and water) and/or RCA SC-2 (hydrochloric acid, hydrogen peroxide and water). The pre-clean process oxidizes the exposed surfaces of the channel members 2080 and the top surfaces of the base portions 212BS to form the interfacial layer 242. The gate dielectric layer 244 is then deposited over the interfacial layer 242 using ALD, CVD, and/or other suitable methods. The gate dielectric layer 244 may include high-K dielectric materials. As used herein, high-k dielectric materials include dielectric materials having a high dielectric constant, for example, greater than that of thermal silicon oxide (˜3.9). In one embodiment, the gate dielectric layer 244 may include hafnium oxide. Alternatively, the gate dielectric layer 244 may include other high-k dielectrics, such as titanium oxide (TiO₂), hafnium zirconium oxide (HfZrO), tantalum oxide (Ta₂O₅), hafnium silicon oxide (HfSiO₄), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), combinations thereof, or other suitable material. After the formation or deposition of the gate dielectric layer 244, a gate electrode layer 246 is deposited over the gate dielectric layer 244. The gate electrode layer 246 may be a multi-layer structure that includes at least one work function layer and a metal fill layer. By way of example, the at least one work function layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), or tantalum carbide (TaC). The metal fill layer may include aluminum (Al), tungsten (W), nickel (Ni), titanium (Ti), ruthenium (Ru), cobalt (Co), platinum (Pt), tantalum silicon nitride (TaSiN), copper (Cu), other refractory metals, or other suitable metal materials or a combination thereof. In various embodiments, the gate electrode layer 246 may be formed by ALD, PVD, CVD, e-beam evaporation, or other suitable process. In various embodiments, a planarization process, such as a CMP process, may be performed to remove excessive materials to provide a substantially planar top surface of the gate structure 250. Referring to FIG. 21, the gate structure 250 wraps around each of the channel members 2080 in the first region 10 and the second region 20. In some embodiments, the planarization also expose planar top surfaces of the channel-top helmet layers 2240. That is, top surfaces of the gate structure 250 and top surfaces of the channel-top helmet layers 2240 are coplanar after the planarization process.

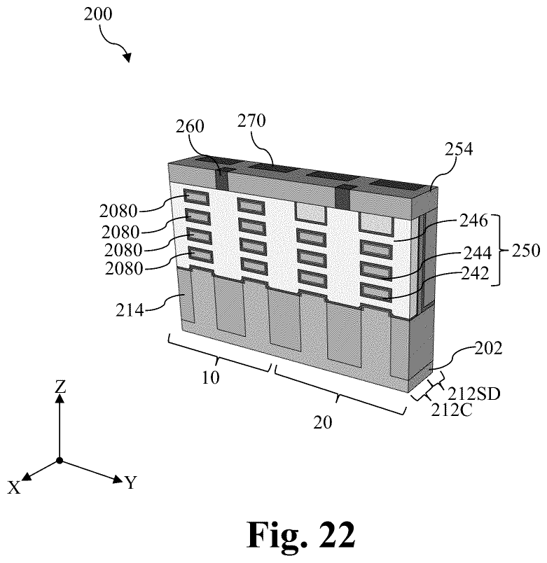

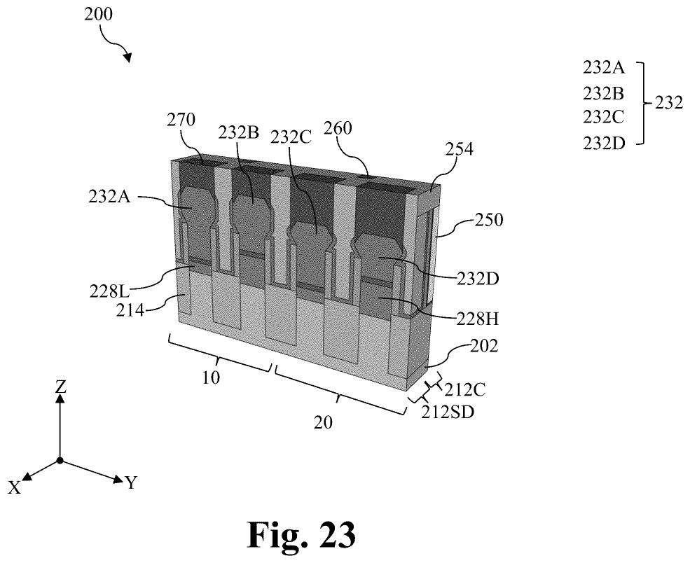

Referring to FIGS. 1 and 22-23, method 100 includes a block 130 where contact structures to the gate structure 250 and the source/drain features 232 are formed. In an example process illustrated in FIGS. 22 and 23, a top interlayer dielectric layer (ILD) 254 is deposited over the planar top surfaces of the gate structure 250 and the channel-top helmet layers 2240. In some embodiments, the top ILD layer 254 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In one embodiment, the top ILD layer 254 includes silicon oxide. The top ILD layer 254 may be deposited by spin-on coating, an FCVD process, or other suitable deposition technique. Source/drain contact openings and gate openings may then be formed through the top ILD layer 254 sequentially or together to expose the source/drain features 232 and the gate structure 250. In one embodiment, the source/drain contact openings are formed to expose one or more of the source/drain features 232. A metal silicide layer is then formed over the exposed surfaces of the source/drain features 232. In an example process, a metal precursor, such as titanium, is first deposited over the exposed surfaces of the source/drain features 232. An anneal process is then performed to bring about silicidation reaction to form the silicide layer. In an alternative process, silicon precursor and metal precursors are introduced in an ALD or CVD process to deposit a silicide layer over on the exposed surfaces of the source/drain features 232. After the formation of the silicide layer, the excess metal precursor may be selectively removed and a metal fill layer, such as tungsten (W), ruthenium (Ru), or cobalt (Co) is deposited in a bottom-up manner to form the source/drain contacts 270 shown in FIGS. 22 and 23. After the formation of the source/drain contacts 270, one or more gate contact openings are formed through the top ILD layer 254 to expose surfaces of the gate structure 250. One or more gate contact plugs 260 are then formed in the gate contact openings. In some instances, the gate contact plugs 260 are formed before the formation of the source/drain contacts 270. It is noted that the presence of the channel-top helmet layer 2240 may affect depths of the source/drain contacts 270. This is because that the resulting source/drain features 232 may have a smaller height due to the implementation of the channel-top helmet layer 2240 and accompanying layers (such as the first sacrificial layer 2062, the second sacrificial layer 2066, the first silicon control layer 2082, and the second silicon control layer 2084). Accordingly, in the depicted embodiments, a depth difference between a source/drain contact with the channel-top helmet layer 2240 and one without is between about 10 nm and about 20 nm. If a channel-top helmet layer 2240 of a greater thickness (along the Z direction) is implemented, the depth difference may be even greater.

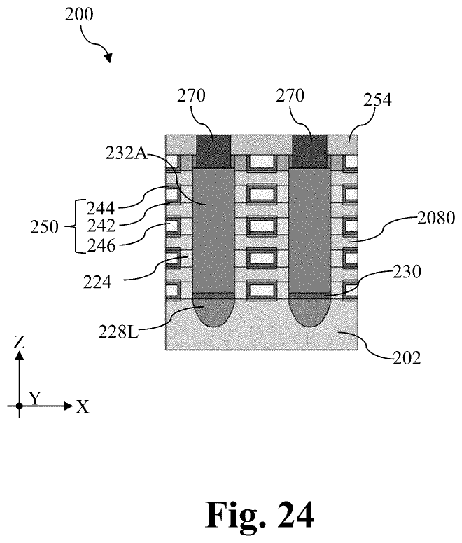

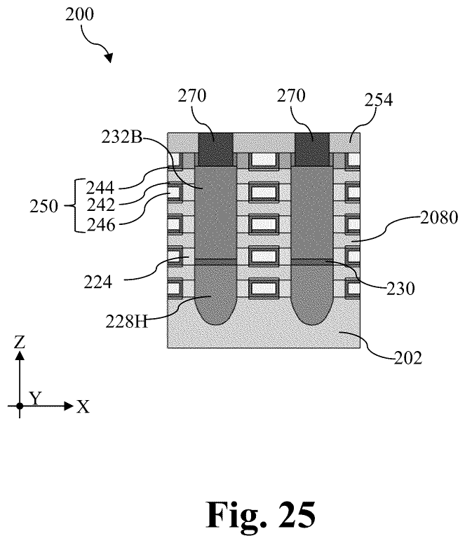

By varying a height of the dummy epitaxial layer 228 and displacing different numbers of top channel members by channel-top helmet layers 2240 of different depths, method 100 of the present disclosure may be used to modulate the effective channel widths (Weff) of GAA transistors. As a basis of comparison, none of the channel members 2080 in the semiconductor device 200 shown in FIG. 24 is displaced by a channel-top helmet layer 2240 or deactivated by the low dummy epitaxial layer 228L. As shown in FIG. 24, the gate structure 250 wraps around each of the four (4) available channel members 2080 with their sidewalls coupled to the first source/drain features 232A. Referring to FIG. 25, the tall dummy epitaxial layer 228H caps sidewalls of the bottommost channel members 2080, thereby deactivating them. As shown in FIG. 25, the gate structure 250 wraps around each of the four (4) channel members 2080 but only three (3) of the four (4) channel members 2080 have their sidewalls coupled to the second source/drain features 232B.

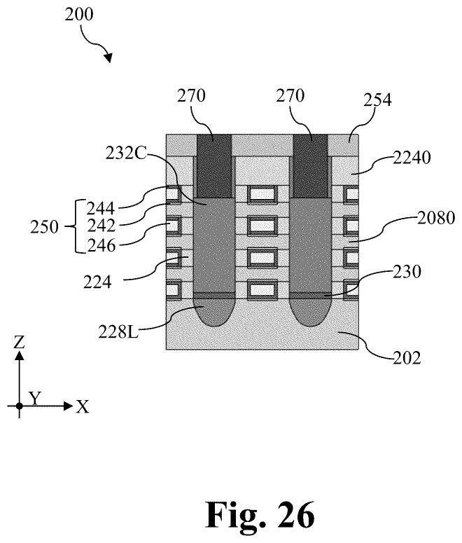

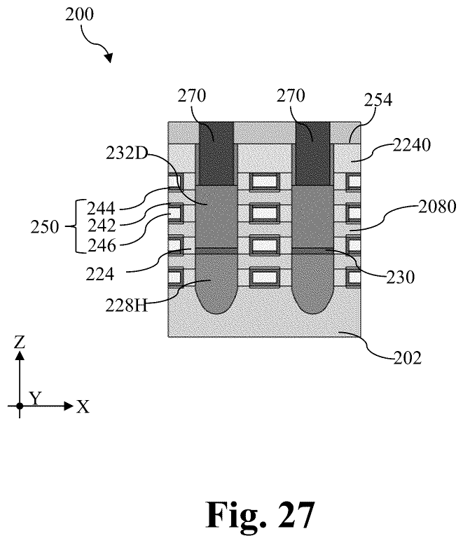

In the embodiments illustrated in FIGS. 26 and 27, channel-top helmet layers 2240 are formed to displace the topmost channel members 2080. In the semiconductor device 200 shown in FIG. 26, the channel-top helmet layers 2240 displace the topmost channel members 2080 such that the gate structure 250 only wraps around three (3) available channel members 2080. In FIG. 26, the low dummy epitaxial layer 228L does not operate to deactivate any channel members 2080. In the semiconductor device 200 shown in FIG. 27, the channel-top helmet layers 2240 displace the topmost channel members 2080 such that the gate structure 250 only wraps around three (3) available channel members 2080. In FIG. 27, the tall dummy epitaxial layer 228H operates to deactivate the bottommost channel members 2080.

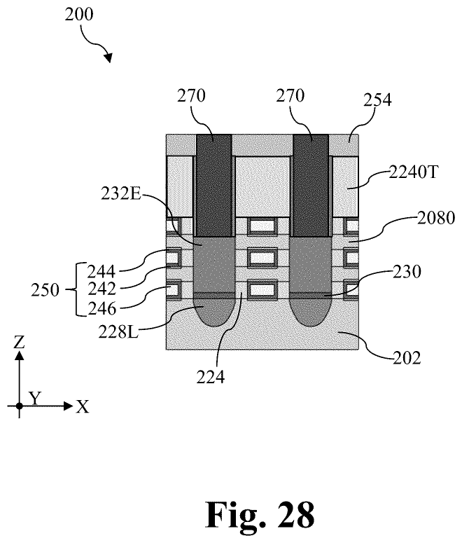

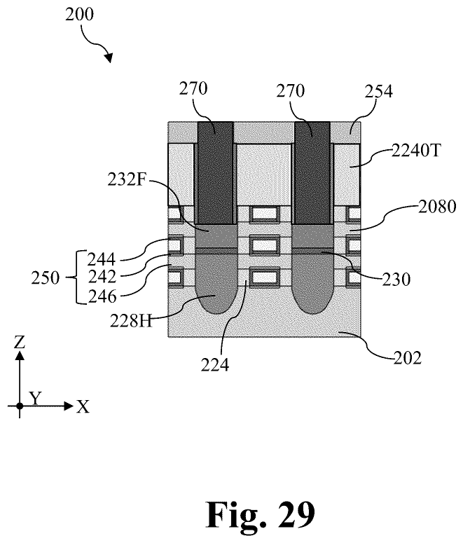

In the embodiments illustrated in FIGS. 28 and 29, thick channel-top helmet layers 2240T are formed to displace two top channel members 2080. In the semiconductor device 200 shown in FIG. 28, the thick channel-top helmet layers 2240T displace two top channel members 2080 such that the gate structure 250 only wraps around two (2) available channel members 2080. In FIG. 28, the low dummy epitaxial layer 228L does not operate to deactivate any channel members 2080. In the semiconductor device 200 shown in FIG. 29, the thick channel-top helmet layers 2240T displace two top channel members 2080 such that the gate structure 250 only wraps around two (2) available channel members 2080. In FIG. 29, the tall dummy epitaxial layer 228H operates to deactivate the bottommost channel members 2080.

When viewed together, embodiments illustrated in FIGS. 24-29 provide different number of channel members 2080, thereby providing different effective channel widths. The semiconductor device 200 in FIG. 24 includes four (4) available channel members 2080, none of which is deactivated or disabled by the tall dummy epitaxial layer 228H. Accordingly, an effective channel width for the semiconductor device 200 in FIG. 24 is about 4 times of the Y-direction width (W, shown in FIG. 21) of each of the channel members 2080, which may be mathematically represented as 4 W. The semiconductor device 200 in FIG. 25 includes four (4) available channel members 2080, a bottommost one of which is deactivated or disabled by the tall dummy epitaxial layer 228H. Accordingly, an effective channel width for the semiconductor device 200 in FIG. 25 is about 3 times of the Y-direction width (W, shown in FIG. 21) of each of the channel members 2080, which may be mathematically represented as 3 W. The semiconductor device 200 in FIG. 26 includes three (3) available channel members 2080, none of which is deactivated or disabled by the tall dummy epitaxial layer 228H. Accordingly, an effective channel width for the semiconductor device 200 in FIG. 26 is about 3 times of the Y-direction width (W, shown in FIG. 21) of each of the channel members 2080, which may be mathematically represented as 3 W. The semiconductor device 200 in FIG. 27 includes three (3) available channel members 2080, a bottommost one of which is deactivated or disabled by the tall dummy epitaxial layer 228H. Accordingly, an effective channel width for the semiconductor device 200 in FIG. 27 is about 2 times of the Y-direction width (W, shown in FIG. 21) of each of the channel members 2080, which may be mathematically represented as 2 W. The semiconductor device 200 in FIG. 28 includes two (2) available channel members 2080, none of which is deactivated or disabled by the tall dummy epitaxial layer 228H. Accordingly, an effective channel width for the semiconductor device 200 in FIG. 28 is about 2 times of the Y-direction width (W, shown in FIG. 21) of each of the channel members 2080, which may be mathematically represented as 2 W. The semiconductor device 200 in FIG. 29 includes two (2) available channel members 2080, a bottommost one of which is deactivated or disabled by the tall dummy epitaxial layer 228H. Accordingly, an effective channel width for the semiconductor device 200 in FIG. 29 is about the Y-direction width (W, shown in FIG. 21) of one of the channel members 2080, which may be mathematically represented as 1 W. Because all of these semiconductor devices 200 shown in FIGS. 24-29 are fabricated using method 100 and from fin-shaped structures (such as the first fin-shaped structure 212A and the second fin-shaped structure 212B shown in FIG. 6) of the same dimensions, they all share the same footprint on the X-Y plane.

In one exemplary aspect, the present disclosure is directed to a semiconductor device. The semiconductor device includes a first base fin and a second base fin extending from a substrate, an isolation feature disposed between the first base fin and the second base fin, a first dummy epitaxial layer disposed on the first base fin, a second dummy epitaxial layer disposed on the second base fin, a first insulator layer over the first dummy epitaxial layer, a second insulator layer over the second dummy epitaxial layer, a first source/drain feature disposed on the first insulator layer, and a second source/drain feature disposed on the second insulator layer. A thickness of the first dummy epitaxial layer measured from a top surface of the first base fin is smaller than a thickness of the second dummy epitaxial layer measured from a top surface of the second base fin.

In some embodiments, the first dummy epitaxial layer and the second dummy epitaxial layer comprise undoped silicon germanium (SiGe) or undoped silicon (Si). In some embodiments, the first insulator layer and the second insulator layer include silicon nitride, silicon oxynitride, silicon oxycarbonitride, silicon oxycarbide, silicon carbonitride, silicon oxide, aluminum oxide, or hafnium oxide. In some implementations, the first insulator layer and the second insulator layer include a thickness between about 3 nm and about 8 nm. In some instances, the semiconductor device further includes a third base fin extending from the substrate, a third dummy epitaxial layer disposed on the third base fin, a third insulator layer over the third dummy epitaxial layer, and a third source/drain feature disposed on the third insulator layer. A top surface of the third source/drain feature is higher than a top surface of the first source/drain feature or a top surface of the second source/drain feature. In some embodiments, the semiconductor device further includes a first source/drain contact disposed over the first source/drain feature, and a third source/drain contact disposed over the third source/drain feature. A height of first source/drain contact is greater than a height of the third source/drain contact. In some implementations, the semiconductor device further includes a first spacer layer disposed along and in contact with sidewalls of the first dummy epitaxial layer, the first insulator layer, and the first source/drain feature.

In another exemplary aspect, the present disclosure is directed to a semiconductor device. The semiconductor device includes a first source/drain feature and a second source/drain feature, a first source/drain contact over the first source/drain feature, a second source/drain contact over the second source/drain feature, a plurality of channel members extending between and in contact with the first source/drain feature and the second source/drain feature, a gate structure wrapping around each of the plurality of channel members, a plurality of inner spacer features interleaving the plurality of channel members and spacing the gate structure apart from sidewalls of the first source/drain feature, and a helmet layer disposed on the gate structure and in contact with a topmost one of the plurality of inner spacer features. The helmet layer is disposed between the first source/drain contact and the second source/drain contact.

In some embodiments, the helmet layer is in contact with a top surface of the gate structure. In some implementations, the first source/drain feature is disposed on a first insulator layer and the second source/drain feature is disposed on a second insulator layer. In some instances, the first insulator layer and the second insulator layer include silicon nitride, silicon oxynitride, silicon oxycarbonitride, silicon oxycarbide, silicon carbonitride, silicon oxide, aluminum oxide, or hafnium oxide. In some embodiments, the first insulator layer is disposed on a first dummy epitaxial layer and the second insulator layer is disposed on a second dummy epitaxial layer. In some instances, the first dummy epitaxial layer and the second dummy epitaxial layer include undoped silicon germanium (SiGe) or undoped silicon (Si).

In yet another exemplary aspect, the present disclosure is directed to a method. The method includes receiving a workpiece that includes a substrate, a stack over the substrate, the stacking including a plurality of channel layers interleaved by a plurality of sacrificial layers, and a top sacrificial layer over the stack, selectively removing the top sacrificial layer, a topmost one of the plurality of channel layers, and a topmost one of the plurality of sacrificial layers over a first region of the work piece while a second region of the workpiece is covered by a hard mask, depositing a replacement sacrificial layer, a high-germanium layer, and a replacement top sacrificial layer over the first region, after the depositing, planarizing the workpiece to expose the top sacrificial layer, forming a first fin-shaped structure from the stack and a portion of the substrate over a second region, forming a second fin-shaped structure from the stack and a portion of the substrate over the first region, forming a dummy gate stack over channel regions of the first fin-shaped structure and the second fin-shaped structure, anisotropically etching source/drain regions of the first fin-shaped structure and the second fin-shaped structure, selectively and partially recessing sidewalls of the plurality of sacrificial layers to form inner spacer recesses, selectively removing the high-germanium layer in the first fin-shaped structure to form a top gap, forming inner spacer features in the inner spacer recesses, forming a helmet feature in the top gap, depositing a first dummy epitaxial layer over the source/drain region of the first fin-shaped structure, depositing a second dummy epitaxial layer over the source/drain region of the second fin-shaped structure, forming a first insulator layer over a top surface of the first dummy epitaxial layer and a second insulator layer over a top surface of the second dummy epitaxial layer, and forming a first source/drain feature over the first insulator layer and a second source/drain feature over the second insulator layer.

In some embodiments, the plurality of sacrificial layers, the replacement sacrificial layer, the high-germanium layer, and the replacement top sacrificial layer include silicon germanium. A first germanium content of the high-germanium layer is greater than a second germanium content of the plurality of sacrificial layers, the replacement sacrificial layer, and the replacement top sacrificial layer. In some implementations, the first germanium content is between about 30% and about 50% and the second germanium content is between about 20% and about 30%. In some implementations, the depositing of the replacement sacrificial layer, the high-germanium layer, and the replacement top sacrificial layer includes depositing a first silicon layer over the replacement sacrificial layer, and depositing a second silicon layer over the high-germanium layer. In some embodiments, the selectively removing of the high-germanium layer further includes removing the first silicon layer and the second silicon layer in the first fin-shaped structure. In some instances, the first dummy epitaxial layer and the second dummy epitaxial layer include undoped silicon germanium (SiGe) or undoped silicon (Si). In some embodiments, the first insulator layer and the second insulator layer include silicon nitride, silicon oxynitride, silicon oxycarbonitride, silicon oxycarbide, silicon carbonitride, silicon oxide, aluminum oxide, or hafnium oxide.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first base fin and a second base fin extending from a substrate;
an isolation feature disposed between the first base fin and the second base fin;
a first dummy epitaxial layer disposed on the first base fin;
a second dummy epitaxial layer disposed on the second base fin;
a first insulator layer over the first dummy epitaxial layer;
a second insulator layer over the second dummy epitaxial layer;
a first source/drain feature disposed on the first insulator layer; and
a second source/drain feature disposed on the second insulator layer,
wherein a thickness of the first dummy epitaxial layer measured from a top surface of the first base fin is smaller than a thickness of the second dummy epitaxial layer measured from a top surface of the second base fin.

2. The semiconductor device of claim 1, wherein the first dummy epitaxial layer and the second dummy epitaxial layer comprise undoped silicon germanium (SiGe) or undoped silicon (Si).

3. The semiconductor device of claim 1, wherein the first insulator layer and the second insulator layer comprise silicon nitride, silicon oxynitride, silicon oxycarbonitride, silicon oxycarbide, silicon carbonitride, silicon oxide, aluminum oxide, or hafnium oxide.

4. The semiconductor device of claim 1, wherein the first insulator layer and the second insulator layer comprise a thickness between about 3 nm and about 8 nm.

5. The semiconductor device of claim 1, further comprising:
a third base fin extending from the substrate;
a third dummy epitaxial layer disposed on the third base fin;
a third insulator layer over the third dummy epitaxial layer; and
a third source/drain feature disposed on the third insulator layer,
wherein a top surface of the third source/drain feature is higher than a top surface of the first source/drain feature or a top surface of the second source/drain feature.

6. The semiconductor device of claim 5, further comprising:
a first source/drain contact disposed over the first source/drain feature; and
a third source/drain contact disposed over the third source/drain feature,
wherein a height of first source/drain contact is greater than a height of the third source/drain contact.

7. The semiconductor device of claim 1, further comprising:
a first spacer layer disposed along and in contact with sidewalls of the first dummy epitaxial layer, the first insulator layer, and the first source/drain feature.

8. A semiconductor structure, comprising:
a first source/drain feature and a second source/drain feature;
a first source/drain contact over the first source/drain feature;
a second source/drain contact over the second source/drain feature;
a plurality of channel members extending between and in contact with the first source/drain feature and the second source/drain feature;
a gate structure wrapping around each of the plurality of channel members;
a plurality of inner spacer features interleaving the plurality of channel members and spacing the gate structure apart from sidewalls of the first source/drain feature; and
a helmet layer disposed on the gate structure and in contact with a topmost one of the plurality of inner spacer features,
wherein the helmet layer is disposed between the first source/drain contact and the second source/drain contact.

9. The semiconductor structure of claim 8, wherein the helmet layer is in contact with a top surface of the gate structure.

10. The semiconductor structure of claim 8,
wherein the first source/drain feature is disposed on a first insulator layer,
wherein the second source/drain feature is disposed on a second insulator layer.

11. The semiconductor structure of claim 10, wherein the first insulator layer and the second insulator layer comprise silicon nitride, silicon oxynitride, silicon oxycarbonitride, silicon oxycarbide, silicon carbonitride, silicon oxide, aluminum oxide, or hafnium oxide.

12. The semiconductor structure of claim 10,
wherein the first insulator layer is disposed on a first dummy epitaxial layer,
wherein the second insulator layer is disposed on a second dummy epitaxial layer.

13. The semiconductor structure of claim 12, wherein the first dummy epitaxial layer and the second dummy epitaxial layer comprise undoped silicon germanium (SiGe) or undoped silicon (Si).

14. A method, comprising:
receiving a workpiece comprising:
a substrate,
a stack over the substrate, the stacking comprising a plurality of channel layers interleaved by a plurality of sacrificial layers, and
a top sacrificial layer over the stack;
selectively removing the top sacrificial layer, a topmost one of the plurality of channel layers, and a topmost one of the plurality of sacrificial layers over a first region of the workpiece while a second region of the workpiece is covered by a hard mask;
depositing a replacement sacrificial layer, a high-germanium layer, and a replacement top sacrificial layer over the first region;
after the depositing, planarizing the workpiece to expose the top sacrificial layer;
forming a first fin-shaped structure from the stack and a portion of the substrate over a second region;
forming a second fin-shaped structure from the stack and a portion of the substrate over the first region;
forming a dummy gate stack over channel regions of the first fin-shaped structure and the second fin-shaped structure;
anisotropically etching source/drain regions of the first fin-shaped structure and the second fin-shaped structure;
selectively and partially recessing sidewalls of the plurality of sacrificial layers to form inner spacer recesses;
selectively removing the high-germanium layer in the first fin-shaped structure to form a top gap;
forming inner spacer features in the inner spacer recesses;
forming a helmet feature in the top gap;
depositing a first dummy epitaxial layer over the source/drain region of the first fin-shaped structure;
depositing a second dummy epitaxial layer over the source/drain region of the second fin-shaped structure;
forming a first insulator layer over a top surface of the first dummy epitaxial layer and a second insulator layer over a top surface of the second dummy epitaxial layer; and
forming a first source/drain feature over the first insulator layer and a second source/drain feature over the second insulator layer.

15. The method of claim 14,
wherein the plurality of sacrificial layers, the replacement sacrificial layer, the high-germanium layer, and the replacement top sacrificial layer comprise silicon germanium,
wherein a first germanium content of the high-germanium layer is greater than a second germanium content of the plurality of sacrificial layers, the replacement sacrificial layer, and the replacement top sacrificial layer.

16. The method of claim 15,
wherein the first germanium content is between about 30% and about 50%,
wherein the second germanium content is between about 20% and about 30%.

17. The method of claim 14, wherein the depositing of the replacement sacrificial layer, the high-germanium layer, and the replacement top sacrificial layer comprises:
depositing a first silicon layer over the replacement sacrificial layer; and
depositing a second silicon layer over the high-germanium layer.

18. The method of claim 17, wherein the selectively removing of the high-germanium layer further comprises removing the first silicon layer and the second silicon layer in the first fin-shaped structure.

19. The method of claim 14, wherein the first dummy epitaxial layer and the second dummy epitaxial layer comprise undoped silicon germanium (SiGe) or undoped silicon (Si).

20. The method of claim 14, wherein the first insulator layer and the second insulator layer comprise silicon nitride, silicon oxynitride, silicon oxycarbonitride, silicon oxycarbide, silicon carbonitride, silicon oxide, aluminum oxide, or hafnium oxide.
